(19) United States
(12) Patent Application Publication
(10) Pub. No.: US 2025/0169332 A1
(43) Pub. Date: May 22, 2025

(54) DISPLAY DEVICE AND METHOD OF FABRICATION FOR THE SAME

(71) Applicant: Samsung Display Co., LTD., Yongin-si (KR)

(72) Inventors: So Young OH, Yongin-si (KR); Jong Woo KIM, Yongin-si (KR); Hyun Sup YOON, Yongin-si (KR); Woo Suk JUNG, Yongin-si (KR); Jae Heung HA, Yongin-si (KR)

(73) Assignee: Samsung Display Co., LTD., Yongin-si (KR)

(21) Appl. No.: 18/747,092

(22) Filed: Jun. 18, 2024

(30) Foreign Application Priority Data
Nov. 20, 2023 (KR) 10-2023-0160641

(51) Int. Cl. H10K 59/80; H10K 102/00

(52) U.S. Cl. CPC H10K 59/873; H10K 2102/351

(57) ABSTRACT

A display device includes a light emitting element layer disposed on a substrate, and an encapsulation layer including a first inorganic encapsulation layer, an organic encapsulation layer, and a second inorganic encapsulation layer sequentially stacked on the light emitting element layer. At least one of the first and the second inorganic encapsulation layer includes a first inorganic layer and a second inorganic layer disposed on the first inorganic layer, the second inorganic layer includes a first surface facing the first inorganic layer, and a second surface opposite to the first surface, a first film density in a region adjacent to the first surface of the second inorganic layer is greater than a second film density in a region adjacent to the second surface of the second inorganic layer, and a film density of the first inorganic layer is greater than the second film density of the second inorganic layer.

### CROSS-REFERENCE TO RELATED APPLICATION(S)

This application claims priority to and benefits of Korean Patent Application No. 10-2023-0160641 under 35 U.S.C. 119, filed on Nov. 20, 2023, in the Korean Intellectual Property Office (KIPO), the entire contents of which are incorporated herein by reference.

### BACKGROUND

### 1. Technical Field

The disclosure relates to a display device and a method of fabrication for the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device, and an organic light emitting display device. Among the flat panel display devices, in the light emitting display device, since each of pixels of a display panel includes a light emitting element capable of emitting light by itself, an image can be displayed without a backlight unit providing light to the display panel.

The display device may further include pixels that emit light, scan lines, data lines, and power lines for driving the pixels, a scan driver that outputs scan signals to the scan lines, and a display driver that outputs data voltages to the data lines.

### SUMMARY

Aspects of the disclosure provide a display device including an encapsulation layer having a small thickness and a method of fabrication for the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device may include a light emitting element layer disposed on a substrate and including a plurality of light emitting elements, and an encapsulation layer including a first inorganic encapsulation layer disposed on the light emitting element layer, an organic encapsulation layer disposed on the first inorganic encapsulation layer, and a second inorganic encapsulation layer disposed on the organic encapsulation layer. At least one of the first inorganic encapsulation layer and the second inorganic encapsulation layer may include a first inorganic layer and a second inorganic layer disposed on the first inorganic layer, the second inorganic layer may include a first surface facing the first inorganic layer, and a second surface opposite to the first surface, a first film density of the second inorganic layer in a region adjacent to the first surface of the second inorganic layer may be greater than a second film density of the second inorganic layer in a region adjacent to the second surface of the second inorganic layer, and a film density of the first inorganic layer may be greater than the second film density of the second inorganic layer.

A thickness of the first inorganic layer may be in a range of about 3 Å to about 20 Å.

The second inorganic layer may further have a third film density, which may be smaller than the first film density and greater than the second film density, between the first surface and the second surface.

The second inorganic layer may further include a region where a film density of the second inorganic layer decreases.

The film density of the second inorganic layer may decrease in a thickness direction.

A thickness of the region where the film density of the second inorganic layer decreases may be about 10 to about 50 times a thickness of the first inorganic layer.

A thickness of the region where the film density of the second inorganic layer decreases may be about 5% to about 40% of a total thickness of the second inorganic layer.

A difference between the film density of the first inorganic layer and the second film density of the second inorganic layer may be greater than or equal to about 0.5.

Each of the first inorganic layer and the second inorganic layer may include silicon nitride.

A refractive index of the first inorganic layer may be greater than or equal to about 1.9.

A refractive index of the second inorganic layer may be in a range of about 1.7 to about 1.8.

The first inorganic encapsulation layer may include the first inorganic layer and the second inorganic layer, and a thickness of the first inorganic encapsulation layer may be less than or equal to about 600 Å.

The second inorganic encapsulation layer may include the first inorganic layer and the second inorganic layer, and a thickness of the second inorganic encapsulation layer may be less than or equal to about 1200 Å.

According to an embodiment of the disclosure, a display device may include a light emitting element layer disposed on a substrate and including a plurality of light emitting elements, a first inorganic encapsulation layer comprising a first inorganic layer disposed on the light emitting element layer and a second inorganic layer disposed on the first inorganic layer, an organic encapsulation layer disposed on the first inorganic encapsulation layer, and an encapsulation layer including a second inorganic encapsulation layer including a third inorganic layer disposed on the organic encapsulation layer, and a fourth inorganic layer disposed on the third inorganic layer. The second inorganic layer may include a region where a film density of the second inorganic layer decreases in a thickness direction, and the fourth inorganic layer may include a region where a film density of the second inorganic layer decreases in the thickness direction.

A film density of the first inorganic layer may be greater than a maximum film density of the second inorganic layer, and a film density of the third inorganic layer may be greater than a maximum film density of the fourth inorganic layer.

Each of a water vapor transmission rate of the first inorganic encapsulation layer and a water vapor transmission rate of the second inorganic encapsulation layer may be less than or equal to about 9*10⁻⁴ g/m² day.

According to an embodiment of the disclosure, a method of fabrication for a display device may include forming a light emitting element layer comprising a plurality of light emitting elements on a substrate, forming a first inorganic encapsulation layer on the light emitting element layer, forming an organic encapsulation layer on the first inorganic encapsulation layer, and forming a second inorganic encapsulation layer on the organic encapsulation layer. The forming of the first inorganic encapsulation layer or the forming of the second inorganic encapsulation layer may include forming a first inorganic layer at a first deposition rate, and forming a second inorganic layer on the first inorganic encapsulation layer at a second deposition rate, and the first deposition rate may be less than the second deposition rate.

The forming of the second inorganic layer may include allowing particles of the first inorganic layer to penetrate into the second inorganic layer.

The forming of the first inorganic layer and the forming of the second inorganic layer may be performed using an aminosilane precursor.

The aminosilane precursor may include at least one of cyclosilazane, trisilylamine, bis(diethylamino)silane (BDEAS), bis(t-butylamino)silane (BTBAS), tris(dimethylamino)silane, tris(isopropylamino)silane, tetrakis(dimethylamino)silane, tri(isopropyl)cyclotrisilazane, and tetramethyldisilazane.

In the display device according to one embodiment, the encapsulation layer may have a small thickness but excellent encapsulation characteristics.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view of a display device according to one embodiment;

FIG. 2 is a plan view showing the display device of FIG. 1;

FIG. 3 is a schematic cross-sectional view taken along line A-A′ of FIG. 2;

FIG. 4 is a schematic cross-sectional view showing one sub-pixel of a display device according to one embodiment;

FIG. 5 is a schematic diagram showing an encapsulation layer of the display device according to one embodiment;

FIG. 6 is an enlarged view of part B of FIG. 5;

FIG. 7 is a schematic cross-sectional view showing an encapsulation layer of the display device according to another embodiment;

FIG. 8 is a schematic cross-sectional view showing an encapsulation layer of the display device according to still another embodiment;

FIGS. 9A to 9C show X-ray reflectivity analysis (XRR) of a high density layer, a low density layer, and a high/low density stacked layer;

FIG. 10 is a flowchart illustrating a method of fabrication for the display device according to one embodiment;

FIG. 11 is a flowchart showing in detail a process of forming a second inorganic encapsulation layer of FIG. 10;

FIGS. 12 to 16 are schematic cross-sectional views sequentially showing a fabrication process of a display device according to one embodiment;

FIG. 17 is a perspective view illustrating a head mounted display according to one embodiment;

FIG. 18 is an exploded perspective view showing an example of the head mounted display of FIG. 17; and

FIG. 19 is a perspective view illustrating a head mounted display according to one embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

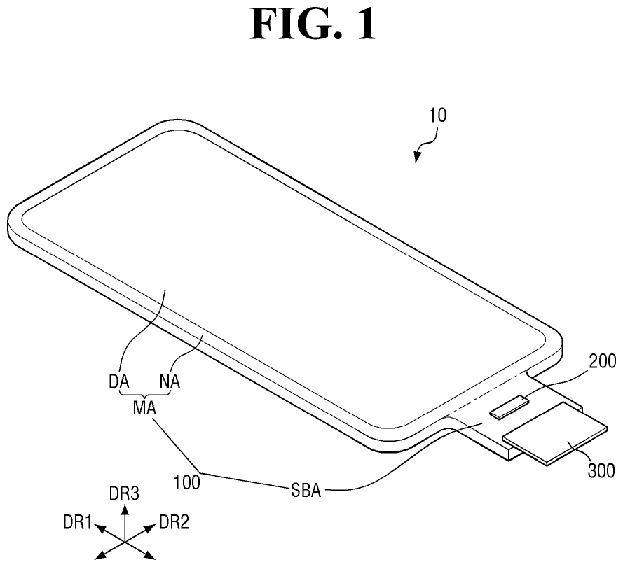

FIG. 1 is a perspective view of a display device according to one embodiment.

Referring to FIG. 1, a display device 10 may be a device for displaying a moving image or a still image. The display device 10 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). In the following, an embodiment in which the display device 10 is an organic light emitting display device is described, but the type of display device 10 is not limited thereto.

In one embodiment, the display device 10 may be formed flat. For example, the display device 10 may be formed substantially flat on a plane defined by a first direction DR1 and a second direction DR2, and may have a thickness (or height) in a third direction DR3. In another embodiment, the display device 10 may include a curved surface in at least a part including an edge region and the like. In another embodiment, the display device 10 may be formed to be flexible so that it can be curved, bent, folded, or rolled.

In one embodiment, with respect to the image display surface of the display device 10, the first direction DR1 may be a lengthwise direction, a column direction, or a vertical direction, and the second direction DR2 may be a direction intersecting the first direction DR1, for example, a widthwise direction, a row direction, or a horizontal direction. The third direction DR3 may be a thickness direction or a height direction of the display device 10.

The display device 10 may include a display panel 100, a driver 200, and a circuit board 300.

The display panel 100 may include a main region MA including a display area DA in which an image is displayed, and a sub-region SBA located on a side of the main region MA.

The main region MA may include the display area DA and a non-display area NA adjacent to the display area DA. The display area DA may be positioned in the center of the main region MA and occupy most of the area in the main region MA. The non-display area NA may be positioned at an edge of the main region MA and may be in contact with the sub-region SBA.

The display area DA may be an area in which pixels are arranged, and may be an area in which an image is displayed by pixels. In one embodiment, the display area DA may be further provided with sensing patterns (e.g., touch electrodes) for detecting a touch input and the like, and the display area DA may include a sensing area for detecting a touch input by the sensing patterns.

In one embodiment, the display area DA may include a long side in the first direction DR1 and a short side in the second direction DR2 and may be formed as a plane having an approximately rectangular shape in a plan view. A corner portion at which the long side and the short side of the display area DA meet may be rounded or right-angled. The shape of the display area DA may be variously changed according to embodiments. For example, the display area DA may be formed in a polygonal shape other than a quadrilateral shape, a circular shape, an elliptical shape, or the like.

The non-display area NA may be located immediately adjacent to the display area DA. In an embodiment, the non-display area NA may surround the display area DA. An embedded circuit may be disposed in the non-display area NA. For example, an embedded circuit including a scan driving circuit or the like may be disposed in the non-display area NA positioned on a side (e.g., the left side or the right side) or sides of the display area DA.

The sub-region SBA may be located on a side of the main region MA. For example, the sub-region SBA may be a region protruding in the first direction DR1 from a side of the main region MA. For example, the sub-region SBA may protrude in the first direction DR1 from the lower end of the main region MA. In one embodiment, the sub-region SBA may have a narrower width than the main region MA. For example, in the second direction DR2, the sub-region SBA may have a narrower width than the main region MA.

Wires and pads may be disposed in the sub-region SBA. For example, in the sub-region SBA, the wires and pads connected to the pixels and/or the embedded circuit positioned in the main region MA and to the driver 200 and/or the circuit board 300 positioned in the sub-region SBA may be disposed. In describing embodiments, the term “connect” may include electrical connection and/or physical connection.

In one embodiment, the driver 200 (e.g., the display driving circuit) may be mounted in the sub-region SBA. The circuit board 300 may be disposed on a part of the sub-region SBA.

The driver 200 may include a data driving circuit to drive pixels. In one embodiment, the driver 200 may be formed as an integrated circuit chip (IC) and disposed in the sub-region SBA. In another embodiment, the driver 200 may be disposed on the circuit board 300 on the sub-region SBA or may be disposed on another circuit board connected to the display panel 100 through the circuit board 300.

The circuit board 300 may be disposed on a part of the sub-region SBA. For example, the circuit board 300 may be bonded on the pads positioned on a portion (e.g., a lower edge) of the sub-region SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip on film (COF), but the disclosure is not limited thereto.

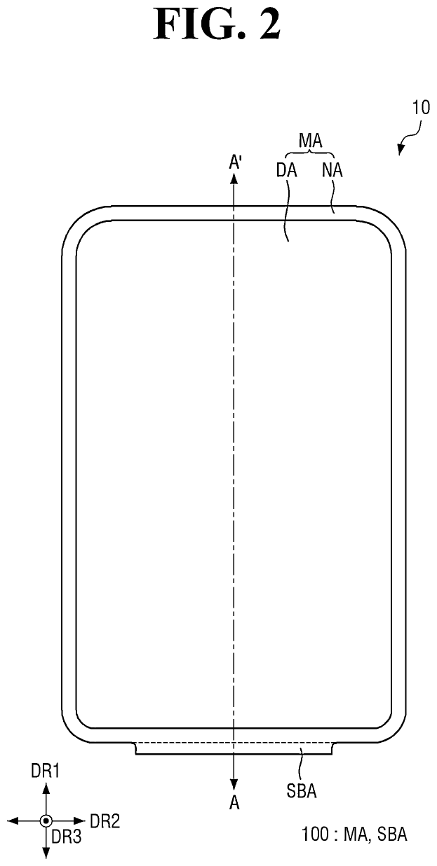

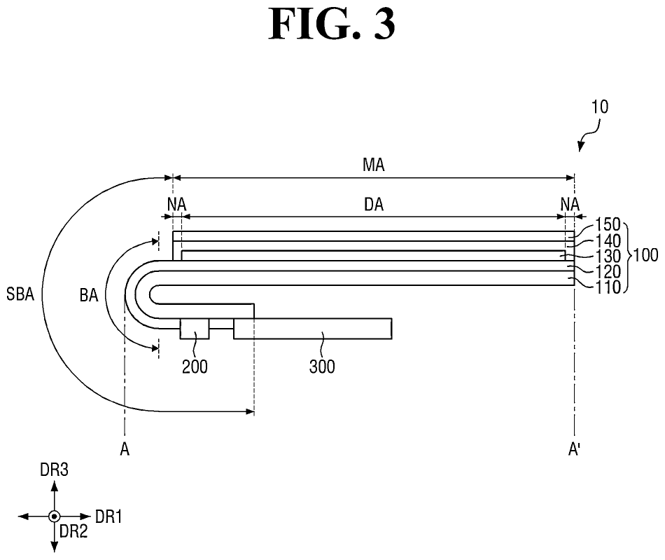

FIG. 2 is a plan view showing the display device of FIG. 1. FIG. 3 is a schematic cross-sectional view taken along line A-A′ of FIG. 2.

FIG. 1 schematically illustrates the display device 10 unfolded without bending, and FIGS. 2 and 3 schematically illustrate the display device 10 bent in the sub-region SBA. FIG. 1 shows the sub-region SBA unfolded alongside the main region MA, and FIGS. 2 and 3 show a part of the sub-region SBA in a bent state.

Referring to FIGS. 2 and 3, the display panel 100 may include a substrate 110 including the main region MA and the sub-region SBA, and a circuit layer 120, a light emitting element layer 130, an encapsulation layer 140, and a color filter layer 150 sequentially disposed on the substrate 110. The circuit layer 120 may be positioned in the main region MA and the sub-region SBA on the substrate 110. The light emitting element layer 130, the encapsulation layer 140, and the color filter layer 150 may be positioned on a part of the substrate 110 and the circuit layer 120. For example, the light emitting element layer 130, the encapsulation layer 140, and the color filter layer 150 may be positioned in the main region MA.

In one embodiment, the display device 10 may further include an additional element disposed on the display panel 100. For example, the display device 10 may further include at least one of a sensor layer (e.g., a touch sensor layer), a polarization layer, and a protective layer (e.g., a window) disposed on the encapsulation layer 140. Each of the sensor layer, the polarization layer and/or the protective layer may be fabricated integrally with the display panel 100 or may be fabricated separately from the display panel 100 and attached to the display panel 100 through an adhesive layer or the like.

The main region MA may include the display area DA and the non-display area NA. The non-display area NA may be located adjacent to the display area DA. For example, the non-display area NA may be an edge area of the main region MA positioned outside the display area DA.

The substrate 110 may include an insulating material such as a polymer resin. For example, the substrate 110 may be made of polyimide or another insulating material. The substrate 110 may be a flexible substrate that can be transformed, such as bending, folding, or rolling. In another embodiment, the substrate 110 may include an insulating material such as glass.

The circuit layer 120 may include pixel circuits and wires. For example, the circuit layer 120 may include circuit elements (e.g., pixel transistors and capacitors) constituting a pixel circuit for each pixel, and wires connected to the pixels. In one embodiment, the circuit layer 120 may further include circuit elements constituting an embedded circuit, such as a scan driving circuit, and wires connected to the embedded circuit.

The light emitting element layer 130 may include light emitting elements disposed in emission areas of the pixels. For example, each of the pixels may include at least one light emitting element and a pixel circuit connected to the light emitting element. Each of the pixels may be located in a pixel region, including the emission area where the light emitting element is disposed and a pixel circuit area where the pixel circuit is disposed. The emission area and the pixel circuit area of each pixel may overlap each other in a plan view, but the disclosure is not limited thereto.

In describing the embodiments, the circuit layer 120 and the light emitting element layer 130 are separately described, but the disclosure is not limited thereto. For example, the circuit layer 120 and the light emitting element layer 130 may be integrated.

The encapsulation layer 140 may cover the light emitting element layer 130 and may extend to the non-display area NA to be in contact with the circuit layer 120. In one embodiment, the encapsulation layer 140 may have a multilayer structure including at least two inorganic encapsulation layers overlapping each other and at least one organic encapsulation layer interposed between the inorganic encapsulation layers.

In one embodiment, the display panel 100 may be bendable in a bending area BA. The bending area BA may be a part of the sub-region SBA and may be spaced apart from the main region MA.

The substrate 110 and the circuit layer 120 may be bendable in the bending area BA corresponding to a partial section of the sub-region SBA. Accordingly, the bezel area recognized by a user as the non-display area NA may be reduced or minimized.

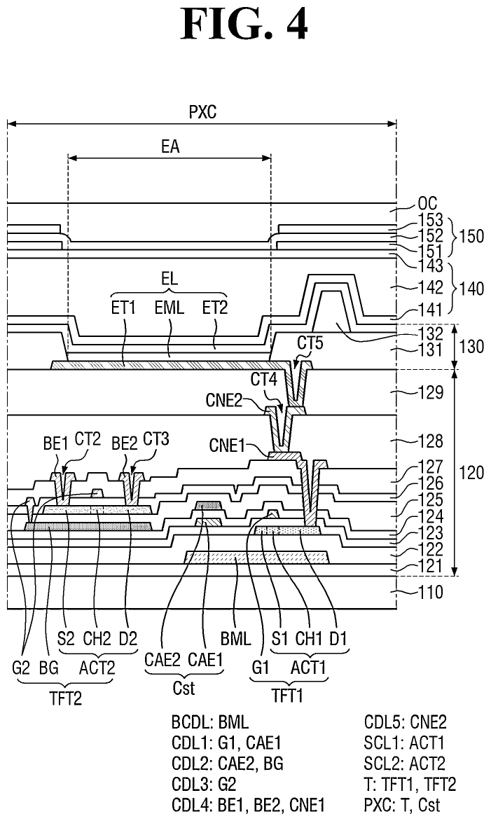

FIG. 4 is a schematic cross-sectional view showing one sub-pixel of a display device according to one embodiment. FIG. 4 is a schematic cross-sectional view showing a part of an area corresponding to one sub-pixel of the display area DA.

Referring to FIG. 4, the display panel 100 may include the substrate 110, and the circuit layer 120, the light emitting element layer 130, the encapsulation layer 140, and the color filter layer 150 disposed on the substrate 110. The circuit layer 120, the light emitting element layer 130, the encapsulation layer 140, and the color filter layer 150 may be sequentially arranged or stacked on the substrate 110 in the third direction DR3.

The substrate 110 may be made of a material having a flexible characteristic capable of bending, folding, rolling, or the like. The substrate 110 may be formed of an insulating material such as a polymer resin. For example, the substrate 110 may be made of polyimide.

The circuit layer 120 may include a pixel circuit PXC and wires. For example, the circuit layer 120 may include circuit elements (e.g., pixel transistors T and a capacitor Cst) constituting the pixel circuit PXC of each sub-pixel, and wires (e.g., various power lines and signal lines including the power lines, the scan lines, emission control lines, and the data lines) electrically connected to the sub-pixels.

Among elements that may be provided in the circuit layer 120, FIG. 4 schematically illustrates a first thin film transistor TFT1 (also referred to as a “first pixel transistor”), a second thin film transistor TFT2 (also referred to as a “second pixel transistor”), and the capacitor Cst included in the pixel circuit PXC of each sub-pixel. The first thin film transistor TFT1 may be first type transistors (e.g., P-type transistors) including a first semiconductor material (e.g., polysilicon) among the pixel transistors T constituting each pixel circuit PXC. FIG. 4 schematically illustrates, as the first thin film transistor TFT1, a transistor connected to the light emitting element EL through at least one connection electrode (e.g., a first connection electrode CNE1 and a second connection electrode CNE2) among the first type transistors. The second thin film transistor TFT2 may be second type transistors (e.g., N-type transistors) including a second semiconductor material (e.g., oxide semiconductor) among the pixel transistors T.

Cross sections of the sub-pixels may be variously changed according to each of the sub-pixels and the type and/or structure of the display panel 100 including the sub-pixel. For example, positions and order of formation of the first thin film transistor TFT1, the second thin film transistor TFT2, and the capacitor Cst may vary according to embodiments.

The circuit layer 120 may include semiconductor layers for forming circuit elements, wires, or the like, conductive layers, and insulating layers disposed between and/or adjacent to the conductive layers and the semiconductor layers. For example, the circuit layer 120 may include a first semiconductor layer SCL1 (e.g., a polysilicon semiconductor layer), a first insulating layer 123 (e.g., a first gate insulating layer), a first conductive layer CDL1 (e.g., a first gate conductive layer), a second insulating layer 124 (e.g., a second gate insulating layer), a second conductive layer CDL2 (e.g., a second gate conductive layer), a third insulating layer 125 (e.g., a first interlayer insulating layer), a second semiconductor layer SCL2 (e.g., an oxide semiconductor layer), a fourth insulating layer 126 (e.g., a third gate insulating layer), a third conductive layer CDL3 (e.g., a third gate conductive layer), a fifth insulating layer 127 (e.g., a second interlayer insulating layer), a fourth conductive layer CDL4 (e.g., a first source-drain conductive layer), and a sixth insulating layer 128 (e.g., a first via layer or a first planarization layer) sequentially disposed on the substrate 110 in the third direction DR3. In one embodiment, the circuit layer 120 may further include a fifth conductive layer CDL5 (e.g., a second source-drain conductive layer) and a seventh insulating layer 129 (e.g., a second via layer or a second planarization layer) sequentially disposed on the sixth insulating layer 128. In one embodiment, the circuit layer 120 may further include a lower conductive layer BCDL disposed between the substrate 110 and the first semiconductor layer SCL1, a barrier layer 121 disposed between the substrate 110 and the lower conductive layer BCDL, and a buffer layer 122 disposed between the lower conductive layer BCDL and the first semiconductor layer SCL1.

The barrier layer 121 may be disposed on the substrate 110. The barrier layer 121 may protect elements disposed on the circuit layer 120 and the light emitting element layer 130 from moisture permeating through the substrate 110 that is susceptible to moisture permeation. The barrier layer 121 may include at least one inorganic layer containing an inorganic insulating material (e.g., silicon nitride, silicon oxide, silicon oxynitride, titanium oxide, aluminum oxide, or another inorganic insulating material). The material of the barrier layer 121 may be variously changed according to embodiments.

The lower conductive layer BCDL may be disposed on the barrier layer 121. The lower conductive layer BCDL may include a lower metal layer BML overlapping the active layer (e.g., a first active layer ACT1 and/or a second active layer ACT2) of the at least one pixel transistor T, and/or at least one wire (or a part of the at least one wire) in a plan view. FIG. 4 schematically illustrates that the lower metal layer BML is disposed to overlap only the first active layer ACT1 of the first thin film transistor TFT1 and capacitor electrodes CAE1 and CAE2 of the capacitor Cst in a plan view, but the disclosure is not limited thereto. For example, the lower metal layer BML may be patterned into a size and/or shape as needed and disposed on a part of the pixel circuit PXC, or may be disposed on the entire surface of the pixel circuit PXC. In one embodiment, the lower metal layer BML may be utilized as a light blocking pattern and/or a back-gate electrode of at least one pixel transistor T, or the like.

The buffer layer 122 may be disposed on the lower conductive layer BCDL to cover the lower conductive layer BCDL. The buffer layer 122 may include at least one inorganic layer containing an inorganic insulating material.

The first thin film transistor TFT1, the second thin film transistor TFT2, and the capacitor Cst may be disposed on a surface of the substrate 110 on which the buffer layer 122 is disposed. The first thin film transistor TFT1 may include the first active layer ACT1 and a first gate electrode G1. The second thin film transistor TFT2 may include the second active layer ACT2 and a second gate electrode G2. In one embodiment, the second thin film transistor TFT2 may include a back-gate electrode BG. The capacitor Cst may include a first capacitor electrode CAE1 and a second capacitor electrode CAE2.

The first semiconductor layer SCL1 may be disposed on the buffer layer 122. The first semiconductor layer SCL1 may include the first active layer ACT1 of the first thin film transistor TFT1.

The first active layer ACT1 may be provided on the first semiconductor layer SCL1 and may include a first semiconductor material (e.g., polysilicon). The first active layer ACT1 may include a first channel region CH1, a first source region S1, and a first drain region D1. The first channel region CH1 may overlap the first gate electrode G1 in the third direction DR3. The first source region S1 may be disposed on a side of the first channel region CH1, and the first drain region D1 may be disposed on another side of the first channel region CH1. The first source region S1 and the first drain region D1 may be regions formed to have conductivity by doping ions or impurities into a semiconductor for forming the first active layer ACT1. In one embodiment, the first source region S1 may be a source electrode of the first thin film transistor TFT1. In another embodiment, the first thin film transistor TFT1 may include a separate source electrode connected to the first source region S1. In one embodiment, the first drain region D1 may be a drain electrode of the first thin film transistor TFT1. In another embodiment, the first thin film transistor TFT1 may include a separate drain electrode connected to the first drain region D1.

The first insulating layer 123 may be disposed on the first semiconductor layer SCL1. The first insulating layer 123 may cover the first semiconductor layer SCL1.

The first conductive layer CDL1 may be disposed on the first insulating layer 123. The first conductive layer CDL1 may include the first gate electrode G1 of the first thin film transistor TFT1. The first gate electrode G1 may be disposed to overlap a part of the first active layer ACT1 (e.g., the first channel region CH1) in a plan view. In one embodiment, the first conductive layer CDL1 may further include at least one wire (or a part of the at least one wire), a metal pattern (e.g., a bridge pattern), and/or a capacitor electrode. For example, the first conductive layer CDL1 may further include the first capacitor electrode CAE1 of the capacitor Cst.

In one embodiment, the first capacitor electrode CAE1 may be integrally formed with the gate electrode of at least one first thin film transistor TFT1. For example, the first capacitor electrode CAE1 and the gate electrode of the first thin film transistor TFT1 may be formed as one conductive pattern, and the second capacitor electrode CAE2 may be disposed to overlap the conductive pattern in a plan view.

The second insulating layer 124 may be disposed on the first conductive layer CDL1. The second insulating layer 124 may cover the first conductive layer CDL1.

The second conductive layer CDL2 may be disposed on the second insulating layer 124. The second conductive layer CDL2 may include an electrode of the capacitor Cst, for example, the second capacitor electrode CAE2. In one embodiment, the second conductive layer CDL2 may further include at least one electrode, a wire (or a part of the at least one wire), and/or a metal pattern (e.g., a bridge pattern). For example, the second conductive layer CDL2 may further include the back-gate electrode BG connected to the second gate electrode G2 of the second thin film transistor TFT2.

The third insulating layer 125 may be disposed on the second conductive layer CDL2. The third insulating layer 125 may cover the second conductive layer CDL2.

The second semiconductor layer SCL2 may be disposed on the third insulating layer 125. The second semiconductor layer SCL2 may include the second active layer ACT2 of the second thin film transistor TFT2.

The second active layer ACT2 may be provided on the second semiconductor layer SCL2 and may include a second semiconductor material (e.g., an oxide semiconductor) different from the first semiconductor material. For example, the second active layer ACT2 may include at least one of IGZO (indium (In), gallium (Ga), zinc (Zn) and oxygen (O)), IGZTO (indium (In), gallium (Ga), zinc (Zn), tin (Sn) and oxygen (O)), and IGTO (indium (In), gallium (Ga), tin (Sn), and oxygen (O)).

The second active layer ACT2 may include a second channel region CH2, a second source region S2, and a second drain region D2. The second channel region CH2 may overlap the second gate electrode G2 in the third direction DR3. The second source region S2 may be disposed on a side of the second channel region CH2, and the second drain region D2 may be disposed on another side of the second channel region CH2. The second source region S2 and the second drain region D2 may be conductive regions by doping ions or impurities into a semiconductor for forming the second active layer ACT2. In one embodiment, the second source region S2 may be a source electrode of the second thin film transistor TFT2. In another embodiment, the second thin film transistor TFT2 may include a separate source electrode connected to the second source region S2. In one embodiment, the second drain region D2 may be a drain electrode of the second thin film transistor TFT2. In another embodiment, the second thin film transistor TFT2 may include a separate drain electrode connected to the second drain region D2.

The fourth insulating layer 126 may be disposed on the second semiconductor layer SCL2. The fourth insulating layer 126 may cover the second semiconductor layer SCL2.

The third conductive layer CDL3 may be disposed on the fourth insulating layer 126. The third conductive layer CDL3 may include the second gate electrode G2 of the second thin film transistor TFT2. The second gate electrode G2 may be disposed to overlap a part of the second active layer ACT2 (e.g., the second channel region CH2) in a plan view. In one embodiment, the third conductive layer CDL3 may further include at least one wire (or a part of the at least one wire), a metal pattern (e.g., a bridge pattern), and/or a capacitor electrode.

In one embodiment, each of the electrodes, the conductive patterns, and/or the wires provided in the lower conductive layer BCDL, the first conductive layer CDL1, the second conductive layer CDL2, and the third conductive layer CLD3 may include a conductive material (e.g., molybdenum (Mo), aluminum (Al), chromium (Cr), gold (Au), titanium (Ti), nickel (Ni), neodymium (Nd), copper (Cu), and at least one of other metals, alloys thereof, or other conductive materials), and may each have a single layer or multilayer structure. For example, each of the electrodes, the conductive patterns, and/or the wires provided in the lower conductive layer BCDL, the first conductive layer CDL1, the second conductive layer CDL2, and the third conductive layer CLD3 may include molybdenum (Mo) or another metal material. At least two conductive layers among the lower conductive layer BCDL, the first conductive layer CDL1, the second conductive layer CDL2, and the third conductive layer CLD3 may include a same material or may include different materials. Materials of each of the lower conductive layer BCDL, the first conductive layer CDL1, the second conductive layer CDL2, and the third conductive layer CLD3 are not limited, and may be variously changed according to embodiments.

The fifth insulating layer 127 may be disposed on the third conductive layer CDL3. The fifth insulating layer 127 may cover the third conductive layer CDL3.

In one embodiment, the first insulating layer 123, the second insulating layer 124, the third insulating layer 125, the fourth insulating layer 126, and the fifth insulating layer 127 may be an inorganic insulating layer including an inorganic insulating material (e.g., silicon nitride, silicon oxide, silicon oxynitride, titanium oxide, aluminum oxide, or another inorganic insulating material), and each may have a single layer or multilayer structure. At least two insulating layers among the first insulating layer 123, the second insulating layer 124, the third insulating layer 125, the fourth insulating layer 126, and the fifth insulating layer 127 may include a same material or may include different materials. Materials of each of the first insulating layer 123, the second insulating layer 124, the third insulating layer 125, the fourth insulating layer 126, and the fifth insulating layer 127 may be variously changed according to embodiments.

The fourth conductive layer CDL4 may be disposed on the fifth insulating layer 127. The fourth conductive layer CDL4 may include the first connection electrode CNE1 (or a drain electrode of the first thin film transistor TFT1), a first bridge electrode BE1 (or a source electrode of the second thin film transistor TFT2), and a second bridge electrode BE2 (or a drain electrode of the second thin film transistor TFT2). The first connection electrode CNE1 may be provided on the fourth conductive layer CDL4 and may be connected to the first drain region D1 of the first active layer ACT1 through a first contact hole CT1 penetrating the first insulating layer 123, the second insulating layer 124, the third insulating layer 125, the fourth insulating layer 126, and the fifth insulating layer 127. The first bridge electrode BE1 may be provided on the fourth conductive layer CDL4 and may be connected to the second source region S2 of the second active layer ACT2 through a second contact hole CT2 penetrating the fourth insulating layer 126 and the fifth insulating layer 127. The second bridge electrode BE2 may be connected to the second drain region D2 of the second active layer ACT2 through a third contact hole CT3 penetrating the fourth insulating layer 126 and the fifth insulating layer 127. In one embodiment, the fourth conductive layer CDL4 may further include at least one wire (or a part of the at least one wire), and/or a metal pattern (e.g., a bridge pattern). For example, the fourth conductive layer CDL4 may include a part of the power line (e.g., the first pixel power line and/or the second pixel power line) provided inside and/or outside the display area DA.

The sixth insulating layer 128 may be disposed on the fourth conductive layer CDL4. The sixth insulating layer 128 may cover the fourth conductive layer CDL4.

The fifth conductive layer CDL5 may be disposed on the sixth insulating layer 128. The fifth conductive layer CDL5 may include the second connection electrode CNE2. The second connection electrode CNE2 may be provided in the fifth conductive layer CDL5 and may be connected to the first connection electrode CNE1 through a fourth contact hole CT4 (or a first via hole) penetrating the sixth insulating layer 128. In one embodiment, the fifth conductive layer CDL5 may further include at least one wire (or a part of the at least one wire), and/or a metal pattern (e.g., a bridge pattern). For example, the fifth conductive layer CDL5 may include a part of the power line (e.g., the first pixel power line and/or the second pixel power line) provided inside and/or outside the display area DA.

In one embodiment, each of the electrodes, the conductive patterns, and/or the wires provided in the fourth conductive layer CDL4 and the fifth conductive layer CDL5 may include a conductive material (e.g., molybdenum (Mo), aluminum (Al), chromium (Cr), gold (Au), titanium (Ti), nickel (Ni), neodymium (Nd), copper (Cu), and at least one of other metals, alloys thereof, or other conductive materials), and may have a single layer or multilayer structure. For example, each of the electrodes, the conductive patterns, and/or the wires provided in the fourth conductive layer CDL4 and the fifth conductive layer CDL5 may be formed of a triple layer structure of titanium/aluminum/titanium (Ti/Al/Ti). The fourth conductive layer CDL4 and the fifth conductive layer CDL5 may include a same material or may include different materials. Materials of each of the fourth conductive layer CDL4 and the fifth conductive layer CDL5 may be variously changed according to embodiments.

The seventh insulating layer 129 may be disposed on the fifth conductive layer CDL5. The seventh insulating layer 129 may cover the fifth conductive layer CDL5.

In one embodiment, the sixth insulating layer 128 and the seventh insulating layer 129 may be an organic insulating layer including an organic insulating material (e.g., an acrylic resin, an epoxy resin, a phenolic resin, a polyamide resin, a polyimide resin, or another organic insulating material) to planarize the circuit layer 120, and may each have a single layer or multilayer structure. The sixth insulating layer 128 and the seventh insulating layer 129 may include a same material or may include different materials. Materials of each of the sixth insulating layer 128 and the seventh insulating layer 129 may be variously changed according to embodiments.

The light emitting element layer 130 may include a pixel defining layer 131 that partitions emission areas EA of the pixels and the respective light emitting elements EL positioned in the respective emission areas EA. In one embodiment, the light emitting element layer 130 may further include a spacer 132 disposed on a part of the pixel defining layer 131.

Each of the light emitting elements EL may include a first electrode ET1 (e.g., an anode electrode) connected to at least one transistor T (e.g., the first thin film transistor TFT1) included in the corresponding sub-pixel through the first connection electrode CNE1 and/or the second connection electrode CNE2, and the light emitting layer EML and a second electrode ET2 (e.g., a cathode electrode) sequentially disposed on the first electrode ET1. In one embodiment, the light emitting element EL may further include a first intermediate layer (e.g., hole layer including a hole transport layer) interposed between the first electrode ET1 and the light emitting layer EML, and a second intermediate layer (e.g., an electron layer including an electron transport layer) interposed between the light emitting layer EML and the second electrode ET2.

The first electrode ET1 of the light emitting element EL may include a conductive material and may be disposed on the circuit layer 120. For example, the first electrode ET1 may be disposed on the seventh insulating layer 129 to correspond to each emission area EA. The first electrode ET1 may be connected to the second connection electrode CNE2 through a fifth contact hole CT5 (or a second via hole) penetrating the seventh insulating layer 129.

In one embodiment, the first electrode ET1 may include transparent conductive metal oxide or a metal material having high reflectivity. For example, the first electrode ET1 may have a single-layer structure including molybdenum (Mo), titanium (Ti), copper (Cu) or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light emitting layer EML of the light emitting element EL may include a high molecular material or a single molecular material. In one embodiment, the light emitting layer EML may be disposed in each sub-pixel, and the light emitting layer EML of each sub-pixel may emit visible light of a color corresponding to the corresponding sub-pixel. In another embodiment, the light emitting layer EML may be a common layer shared by the sub-pixels of different colors, and a wavelength conversion layer and/or color filters corresponding to the color (or wavelength band) of light desired to be emitted from each sub-pixel may be arranged in the emission areas EA of at least some of the sub-pixels.

The second electrode ET2 of the light emitting element EL may include a conductive material and may be connected to the second pixel power line. In one embodiment, the second electrode ET2 may be a common layer formed across the entire display area DA and cover the light emitting layer EML and the pixel defining layer 131. In one embodiment, the second electrode ET2 may be formed of a transparent conductive oxide (TCO) such as ITO or IZO capable of transmitting light or a semi-transmissive conductive material such as magnesium (Mg), silver (Ag), or an alloy of magnesium (Mg) and silver (Ag). In case that the second electrode ET2 is made of a semi-transmissive conductive material, an improvement in light output efficiency due to a micro cavity effect may be achieved.

In an embodiment, a capping layer (not shown) may be disposed on the second electrode ET2. The capping layer may include an organic or inorganic insulating material to cover the light emitting element EL. The capping layer may prevent the light emitting element EL from being damaged by external air. In an embodiment, the capping layer may include an organic material such as a-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The pixel defining layer 131 may have an opening corresponding to each of the emission areas EA and may surround the emission areas EA in a plan view. For example, the pixel defining layer 131 may be formed to cover an edge of the first electrode ET1 of the light emitting element EL and may include an opening exposing the remaining portion of the first electrode ET1. A region where the exposed first electrode ET1 and the light emitting layer EML overlap (or a region including the same) in a plan view may be defined as the emission area EA of each pixel PX.

In one embodiment, the pixel defining layer 131 may include at least one organic layer containing an organic insulating material. For example, the pixel defining layer 131 may include at least one of a polyacrylic resin, an epoxy resin, a phenolic resin, a polyamide resin, a polyimide resin, an unsaturated polyester resin, a polyphenylene ether resin, a polyphenylenesulfide resin, benzocyclobutene (BCB), or another organic insulating material.

Although not shown in the drawing, a spacer may be disposed on a part of the pixel defining layer 131. The spacer may include at least one organic layer containing an organic insulating material. In one embodiment, the spacer and the pixel defining layer 131 may include a same material or different materials. The organic insulating material constituting the spacer is not particularly limited and may be variously changed according to embodiments.

The encapsulation layer 140 may be disposed on the light emitting element layer 130 in the main region MA. For example, the encapsulation layer 140 may be disposed in the display area DA and the non-display area NA and cover the light emitting element layer 130. The encapsulation layer 140 may block the permeation of oxygen or moisture into the light emitting element layer 130, and may reduce electrical or physical impacts to the circuit layer 120 and the light emitting element layer 130.

In one embodiment, the encapsulation layer 140 may include a first inorganic encapsulation layer 141, an organic encapsulation layer 142, and a second inorganic encapsulation layer 143 sequentially disposed on the light emitting element layer 130. The first inorganic encapsulation layer 141 and the second inorganic encapsulation layer 143 may include an inorganic insulating material, and the organic encapsulation layer 142 may include an organic material. For example, the first inorganic encapsulation layer 141 and the second inorganic encapsulation layer 143 may include an inorganic insulating material such as aluminum oxide, titanium oxide, tantalum oxide, hafnium oxide, zinc oxide, silicon oxide, silicon nitride, and/or silicon oxynitride, but the disclosure is not limited thereto. For example, the organic encapsulation layer 142 may include an organic material such as a polymer such as an acrylic resin, an epoxy resin, polyimide, or polyethylene, but the disclosure is not limited thereto.

Although an embodiment illustrates the encapsulation layer 140 in which the organic encapsulation layer 142 is disposed between two different inorganic encapsulation layers 141 and 143, the disclosure is not limited thereto. In another embodiment, the organic encapsulation layer 142 may be omitted, and the encapsulation layer 140 may have a structure in which at least one or more layers of inorganic encapsulation layers are stacked each other.

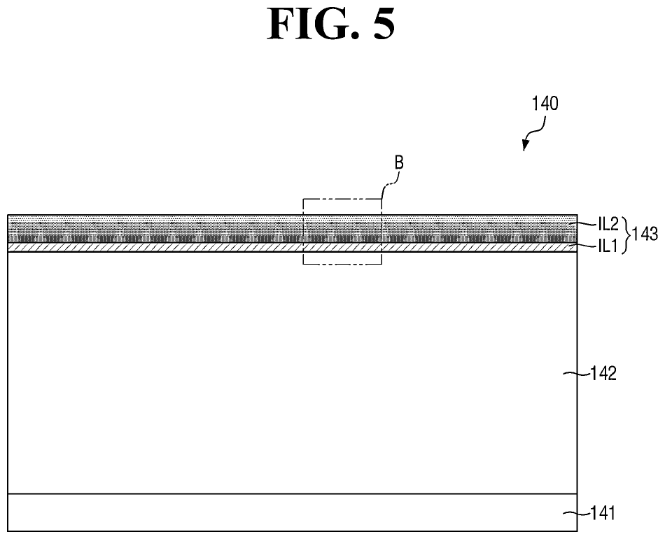

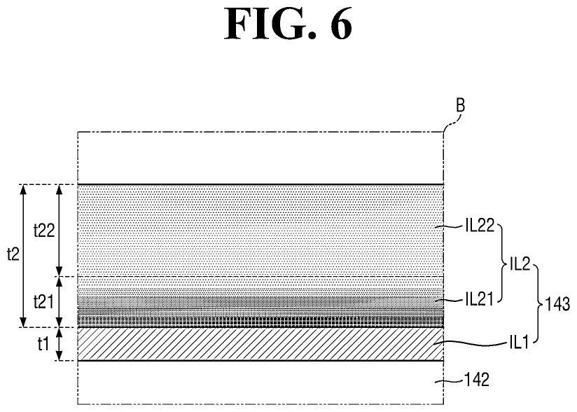

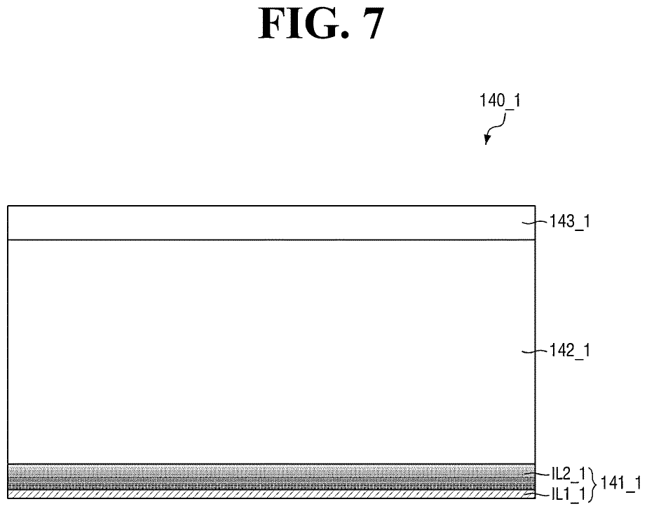

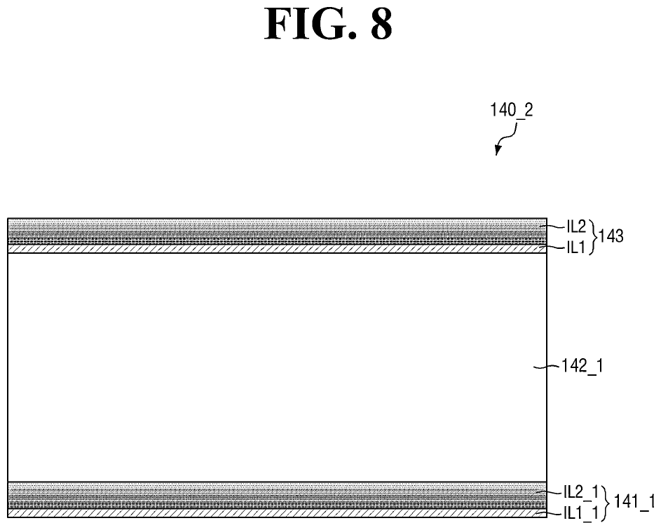

FIG. 5 is a schematic diagram showing the encapsulation layer 140 of the display device 10 according to one embodiment. FIG. 6 is an enlarged view of part B of FIG. 5. FIG. 7 is a schematic cross-sectional view showing an encapsulation layer 140_1 of the display device 10 according to another embodiment. FIG. 8 is a schematic cross-sectional view showing an encapsulation layer 140_2 of the display device 10 according to still another embodiment.

At least one of the first inorganic encapsulation layer 141 and the second inorganic encapsulation layer 143 may include a first inorganic layer IL1, and a second inorganic layer IL2 disposed on the first inorganic layer IL1. The first inorganic encapsulation layer 141 and/or the second inorganic encapsulation layer 143 may have a relatively small thickness although it has a structure in which multiple layers are stacked each other. The first inorganic encapsulation layer 141 and/or the second inorganic encapsulation layer 143 may include multiple inorganic insulating layers to serve as an encapsulator for the display panel 100 while having a small thickness.

According to one embodiment, the first inorganic layer IL1 and the second inorganic layer IL2 may include a same material, but may have some different physical properties or characteristics. The first inorganic layer IL1 and the second inorganic layer IL2 may be formed from a same material, but formed under different fabrication processes or conditions, so that some physical properties of the first inorganic layer IL1 and the second inorganic layer IL2 may be different from each other. For example, the first inorganic layer IL1 and the second inorganic layer IL2 may each include silicon nitride (SiNₓ), but some physical properties of the first inorganic layer IL1 and the second inorganic layer IL2 may be different from each other. The content x of nitrogen contained in the first inorganic layer IL1 and the second inorganic layer IL2 may be the same or different from each other.

Referring to FIGS. 5 and 6, in the display device 10, the second inorganic encapsulation layer 143 of the encapsulation layer 140 may have a structure in which one or more layers of inorganic insulating layers are stacked each other. In an embodiment, the second inorganic encapsulation layer 143 may include the first inorganic layer IL1 and the second inorganic layer IL2 sequentially stacked, and the first inorganic layer IL1 may be in contact with the organic encapsulation layer 142.

The first inorganic layer IL1 may have a relatively high density and a small thickness t1. The film density of the first inorganic layer IL1 may be greater than the film density of the second inorganic layer IL2. In one embodiment, the film density of the first inorganic layer IL1 may be greater than or equal to about 2.6 g/cm³. In another embodiment, the film density of the first inorganic layer IL1 may be greater than or equal to about 2.7 g/cm³. In one embodiment, the film density of the first inorganic layer IL1 may be less than or equal to about 2.9 g/cm³. In another embodiment, the film density of the first inorganic layer IL1 may be less than or equal to about 2.8 g/cm³.

The thickness t1 of the first inorganic layer IL1 may be significantly smaller than a thickness t2 of the second inorganic layer IL2. In one embodiment, the thickness t1 of the first inorganic layer IL1 may be in a range of about 3 Å to about 20 Å. In another embodiment, the thickness t1 of the first inorganic layer IL1 may be in a range of about 5 Å to about 10 Å. In the above range, the first inorganic layer IL1 having a high density may be formed in a short tact time.

The second inorganic layer IL2 may have a lower density than the first inorganic layer IL1, and may include a region where the film density decreases. The second inorganic layer IL2 may include a region IL21 where the film density decreases from the interface with the first inorganic layer IL1. The low density second inorganic layer IL2 may be formed on the high density first inorganic layer IL1, and the particles of the high density first inorganic layer IL1 may serve as seeds in the formation of the second inorganic layer IL2. In an embodiment, the particles of the first inorganic layer IL1 may penetrate between loose portions of the particles of the second inorganic layer IL2. Accordingly, the high density first inorganic layer IL1 may affect the film density of the second inorganic layer IL2 disposed on the first inorganic layer IL1, and thus the second inorganic layer IL2 may have the region IL21 where the film density decreases in the thickness direction at its lower portion.

The second inorganic layer IL2 may have a first surface facing the first inorganic layer IL1 and a second surface opposite to the first surface. The second surface may face the sensor layer or the color filter layer 150, which will be described below. The second inorganic layer IL2 may have a first film density in a region adjacent to the first surface, and may have a second film density in a region adjacent to the second surface. The first film density of the second inorganic layer IL2 may be greater than the second film density. The film density of the first inorganic layer IL1 may be greater than the first and second film densities of the second inorganic layer IL2 and greater than the maximum film density of the second inorganic layer IL2. The first film density may be measured on the first surface of the second inorganic layer IL2, and the second film density may be measured on the second surface of the second inorganic layer IL2. The film density of the second inorganic layer IL2 may vary depending on the height or depth in a region adjacent to the first surface.

The film density of the second inorganic layer IL2 may gradually decrease from the bottom (the first surface) to a certain thickness t21. The film density may decrease gradually or exponentially in the thickness direction. The second inorganic layer IL2 may include a region IL22 where the film density is uniformly maintained on top of the region IL21 where the film density decreases. The region IL21 of the second inorganic layer IL2 where the film density decreases may be from the first surface of the second inorganic layer IL2 having the first film density to a point (or surface) where the second film density is reached. The thickness t21 of the region IL21 of the second inorganic layer IL2 where the film density decreases may be the minimum distance from the first surface (bottom surface) of the second inorganic layer IL2 to the point of the second film density.

In one embodiment, the thickness t21 of the region IL21 of the second inorganic layer IL2 where the film density decreases may be about 10 to about 50 times the thickness t1 of the first inorganic layer IL1. In another embodiment, the thickness t21 of the region IL21 of the second inorganic layer IL2 where the film density decreases may be about 15 to about 35 times the thickness t1 of the first inorganic layer IL1. In one embodiment, the thickness t21 of the region IL21 of the second inorganic layer IL2 where the film density decreases may be about 5% to about 40% of the total thickness t2 of the second inorganic layer IL2. In another embodiment, the thickness t21 of the region IL21 of the second inorganic layer IL2 where the film density decreases may be about 10% to about 35% of the total thickness t2 of the second inorganic layer IL2. By adjusting process conditions such as the deposition rate of the second inorganic layer IL2, the thickness t21 of the region IL21 of the second inorganic layer IL2 where the film density decreases may be adjusted. In the above range, moisture permeation may be prevented due to the high density of the lower portion of the second inorganic layer IL2 without affecting the optical properties.

The second inorganic layer IL2 may have a third film density that is smaller than the first film density and greater than the second film density. The point of the third film density may be located between the first and second surfaces of the second inorganic layer IL2, and may be located at a height lower than the thickness t21 of the region IL21 of the second inorganic layer IL2 where the film density decreases.

In the second inorganic layer IL2, the region IL21 where the film density decreases and the region IL22 where the film density is uniformly maintained may not be physically distinguished. The region IL22 of the second inorganic layer IL2 where the film density is uniformly maintained may have a thickness of t22.

In one embodiment, the second film density of the second inorganic layer IL2 may be greater than or equal to about 1.8 g/cm³. In another embodiment, the second film density of the second inorganic layer IL2 may be greater than or equal to about 1.9 g/cm³. In one embodiment, the second film density of the second inorganic layer IL2 may be less than or equal to about 2.2 g/cm³. In another embodiment, the second film density of the second inorganic layer IL2 may be less than or equal to about 2.1 g/cm³.

In one embodiment, the difference between the film density of the first inorganic layer IL1 and the second film density of the second inorganic layer IL2 may be greater than or equal to about 0.5. The difference between the film density of the first inorganic layer IL1 and the second film density of the second inorganic layer IL2 may not be smaller than about 0.5. In another embodiment, the difference between the film density of the first inorganic layer IL1 and the second film density of the second inorganic layer IL2 may be greater than or equal to about 0.6. The difference between the film density of the first inorganic layer IL1 and the second film density of the second inorganic layer IL2 may not be smaller than about 0.6. In one embodiment, the difference between the film density of the first inorganic layer IL1 and the second film density of the second inorganic layer IL2 may be less than or equal to about 0.9. The difference between the film density of the first inorganic layer IL1 and the second film density of the second inorganic layer IL2 may not exceed about 0.9. In another embodiment, the difference between the film density of the first inorganic layer IL1 and the second film density of the second inorganic layer IL2 may be less than or equal to about 0.8. The difference between the film density of the first inorganic layer IL1 and the second film density of the second inorganic layer IL2 may not exceed about 0.8. In the above range, the density of the lower portion of the second inorganic layer IL2 may increase, thereby preventing moisture permeation.

The thickness t2 of the second inorganic layer IL2 may be significantly greater than the thickness t1 of the first inorganic layer IL1. The thickness t2 of the second inorganic layer IL2 may be about 50 to about 200 times the thickness t1 of the first inorganic layer IL1.

As shown in FIGS. 5 and 6, a thickness t1+t2 of the second inorganic encapsulation layer 143 including the high density first inorganic layer IL1 and the low density second inorganic layer IL2 may be less than or equal to about 1200 Å. The thickness t1+t2 of the second inorganic encapsulation layer 143 may be greater than or equal to about 200 Å. Even if the second inorganic encapsulation layer 143 has a multilayer structure, the second inorganic encapsulation layer 143 may have a small thickness.

The refractive index of the first inorganic layer IL1 may be greater than the refractive index of the second inorganic layer IL2. In the region of the second inorganic layer IL2 where the film density decreases, the refractive index may also decrease. The refractive index of the first inorganic layer IL1 may be greater than the maximum refractive index of the second inorganic layer IL2. In one embodiment, the refractive index of the first inorganic layer IL1 may be greater than or equal to about 1.9. The refractive index of the first inorganic layer IL1 may be less than or equal to 2.1. In one embodiment, the refractive index of the second inorganic layer IL2 may be in a range of about 1.7 to about 1.8.

The film density and the thickness may be measured with an Xray reflectometer (XRR) (D8 ADVANCE Plus, Bruker). In the specification, the refractive index may be measured using an optical measuring instrument such as an ellipsometer, a spectral reflectometer, or the like. The ellipsometer may measure the refractive index by measuring the amount of change in polarization of incident light and reflected light with respect to the inorganic layer and calculating the thickness and complex refractive index of the inorganic layer. The spectral reflectometer may measure the refractive index of the inorganic layer by comparing the intensity of light acquired by changing the wavelength. The refractive index may be a value measured at room temperature and normal pressure.

In one embodiment, a water vapor transmission rate (WVTR) of the second inorganic encapsulation layer 143 may be less than or equal to about 9*10⁻⁴ g/m² day. The second inorganic encapsulation layer 143 may have a multilayer structure, yet have a small thickness described above, and have excellent barrier properties.

The water vapor transmission rate (WVTR) may be a numerical value of moisture permeability that represents the amount of moisture passing through a particular film or layer in a unit area for a unit time, and may be measured according to the regulations in ASTM F1249. The water vapor transmission rate (WVTR) may be measured using Mocon's AQUATRAN 2 or AQUATRAN 3 equipment.

The first inorganic layer IL1 may be in contact with the organic encapsulation layer 142 on the bottom surface and may be in contact with the second inorganic layer IL2 on the top surface. The second inorganic layer IL2 may be in contact with the first inorganic layer IL1 on the bottom surface (the first surface), and may be in contact with the sensor layer or the color filter layer 150 on the top surface (the second surface).

FIG. 7 is a schematic cross-sectional view showing an encapsulation layer 140_1 of the display device 10 according to another embodiment. The encapsulation layer 140_1 of FIG. 7 may differ from the encapsulation layer 140 of FIG. 5 in that a first inorganic encapsulation layer 141_1, instead of a second inorganic encapsulation layer 143_1, includes a first inorganic layer IL1_1 and a second inorganic layer IL2_1.

The first inorganic layer IL1_1 may be in contact with the second electrode ET2, the capping layer (not shown), or the pixel defining layer 131 on the bottom surface, and may be in contact with the second inorganic layer IL2_1 on the top surface. The second inorganic layer IL2_1 may be in contact with the first inorganic layer IL1_1 on the bottom surface (a first surface), and may be in contact with an organic encapsulation layer 142_1 on the top surface (a second surface).

The thickness of the first inorganic encapsulation layer 141_1 including the high density first inorganic layer IL1_1 and the low density second inorganic layer IL2_1 may be less than or equal to about 600 Å. The thickness of the first inorganic encapsulation layer 141_1 may be greater than or equal to about 100 Å. Even if the first inorganic encapsulation layer 141_1 has a multilayer structure, the first inorganic encapsulation layer 141_1 may have a small thickness.

Except as otherwise noted, the description of the first inorganic layer IL1 and the second inorganic layer IL2 described above in FIGS. 5 and 6 may be applied to the first inorganic layer IL1_1 and the second inorganic layer IL2_1 of the first inorganic encapsulation layer 141_1 of FIG. 7.

FIG. 8 is a schematic cross-sectional view showing an encapsulation layer 140_2 of the display device 10 according to still another embodiment. The encapsulation layer 140_2 of FIG. 8 may differ from the encapsulation layer 140 of FIG. 5 in that the first inorganic encapsulation layer 141_1 as well as the second inorganic encapsulation layer 143 may include the first inorganic layer IL1_1 and the second inorganic layer IL2_1.

In FIG. 8, the physical properties of the first inorganic layer IL1_1 of the first inorganic encapsulation layer 141_1 and the physical properties of the first inorganic layer IL1 of the second inorganic encapsulation layer 143 may be the same or different from each other, and the physical properties of the second inorganic layer IL2_1 of the first inorganic encapsulation layer 141_1 and the physical properties of the second inorganic layer IL2 of the second inorganic encapsulation layer 143 may be the same or different from each other.

The description of the first inorganic layer IL1_1 and the second inorganic layer IL2_1 described above in FIG. 7 may be applied to the first inorganic layer IL1_1 and the second inorganic layer IL2_1 of the first inorganic encapsulation layer 141_1 in FIG. 8, and the description of the first inorganic layer IL1 and the second inorganic layer IL2 described above in FIGS. 5 and 6 may be applied to the first inorganic layer IL1 and the second inorganic layer IL2 of the second inorganic encapsulation layer 143 in FIG. 8.

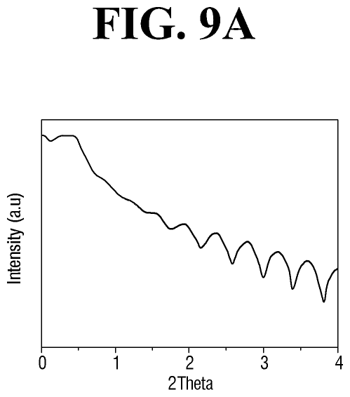

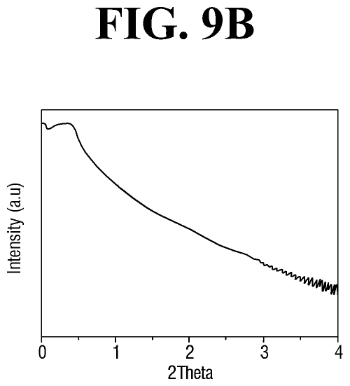

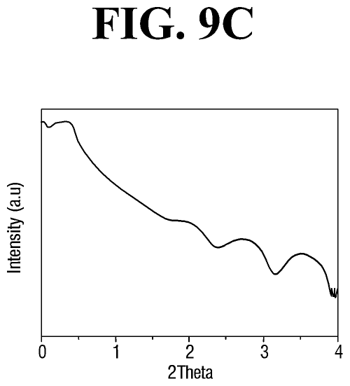

FIGS. 9A to 9C shows X-ray reflectivity analysis (XRR) of a high density layer, a low density layer, and a high/low density stacked layer. FIGS. 9A to 9C show X-ray reflectivity analysis (XRR) of a high density layer, a low density layer, and a stacked layer of a very thin high density layer and a low density layer disposed on the high density layer, respectively. In the case of a high density inorganic layer (see FIG. 9A), large oscillations are observed in a region where a 2theta value is high, and in the case of a low density inorganic layer (see FIG. 9B), small oscillations are observed in a region where the 2theta value is high. In the case of a high density and low density stacked layer (see FIG. 9C), large oscillations are observed in a region where the 2theta value is high, indicating that the high density inorganic layer affects the low density inorganic layer. In other words, it can be seen that the lower portion of the thick low density layer has become highly dense. The fact that the high density layer affects the low density layer may be confirmed through TEM-EDS, TOF-SIMS, or the like in addition to XRR analysis.

Referring back to FIG. 4, the display device 10 may include the color filter layer 150 disposed on the encapsulation layer 140. The color filter layer 150 may include multiple color filters 151, 152, and 153. Each of the color filters 151, 152, and 153 may include a filtering pattern area and a light blocking area. The filtering pattern area may be formed in the emission area EA, and may form a light exit area from which light emitted from the emission area EA exits. The light blocking area may be an area through which light cannot pass due to the stacking of the color filters 151, 152, and 153.

The color filters 151, 152, and 153 may include a first color filter 151, a second color filter 152, and a third color filter 153 disposed to respectively correspond to emission areas EA. The color filters 151, 152, and 153 may contain a colorant, such as a dye or a pigment, that absorbs light in a wavelength band other than a specific wavelength band, and may be arranged to correspond to the color of the light emitted from the emission area EA. For example, the first color filter 151 may be a red color filter that transmits only a first light that is red. The second color filter 152 may be a green color filter that transmits only a second light that is green, and the third color filter 153 may be a blue color filter that transmits only a third light that is blue. FIG. 4 schematically illustrates that only the filtering pattern area of the second color filter 152 overlaps the emission area EA in a plan view, but the emission areas of other adjacent sub-pixels may overlap the filtering pattern area of the first color filter 151 or the filtering pattern area of the third color filter 153 in a plan view.

The display device 10 may reduce the intensity of reflected light caused by external light as the color filters 151, 152, and 153 are arranged overlappingly with each other in a plan view. Further, the color of the reflected light caused by the external light may be controlled by adjusting the arrangement, shape, area, and the like of the color filters 151, 152, and 153 in a plan view.

An overcoat layer OC may be disposed on the color filter layer 150 and planarize the top surface of the color filters 151, 152, and 153. The overcoat layer OC may be a colorless light transmissive layer that does not have a color in a visible light band. For example, the overcoat layer OC may include a colorless light transmissive organic material such as an acrylic resin.

Hereinafter, a fabrication method of the display device 10 will be described with reference to drawings.

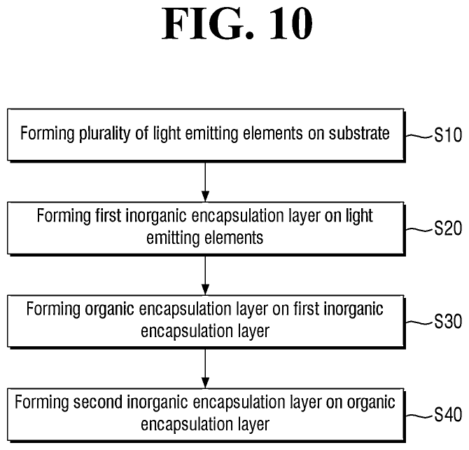

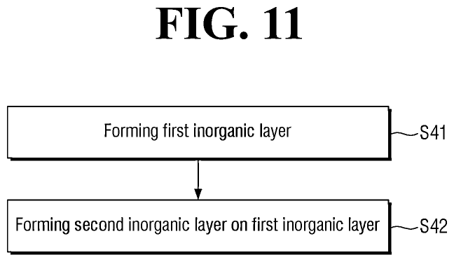

FIG. 10 is a flowchart illustrating a method of fabrication for the display device according to one embodiment. FIG. 11 is a flowchart showing in detail a process of forming a second inorganic encapsulation layer of FIG. 10.

Referring to FIGS. 10 and 11, the fabrication method of the display device 10 according to one embodiment may include forming the light emitting elements EL on the substrate (step S10), forming the first inorganic encapsulation layer 141 on the light emitting elements EL (step S20), forming the organic encapsulation layer 142 on the first inorganic encapsulation layer 141 (step S30), and forming the second inorganic encapsulation layer 143 on the organic encapsulation layer 142 (step S40). Step S40 of forming the second inorganic encapsulation layer 143 may include forming the first inorganic layer IL1 (step S41) and forming the second inorganic layer IL2 on the first inorganic layer IL1 (step S42). The second inorganic encapsulation layer 143 of the display device 10 may include the inorganic layers IL1 and IL2 formed by different deposition processes.

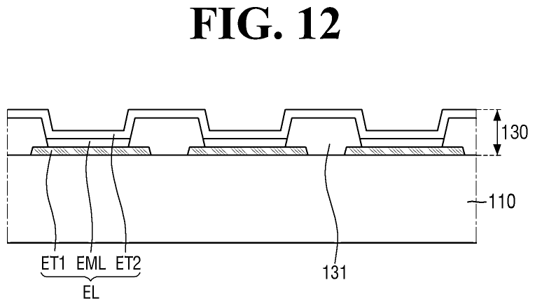

FIGS. 12 to 16 are schematic cross-sectional views sequentially showing a fabrication process of a display device according to one embodiment.

Referring to FIG. 12, the light emitting elements EL may be formed on the substrate 110 (step S10) to form the light emitting element layer 130. The pixel defining layer 131 may be formed on the substrate 110, and the light emitting elements EL may be formed in openings of the pixel defining layer 131. The structure of the pixel defining layer 131 and the light emitting elements EL may be the same as described above. Each of these formation processes may be performed by a typical patterning process, a deposition process, or the like.

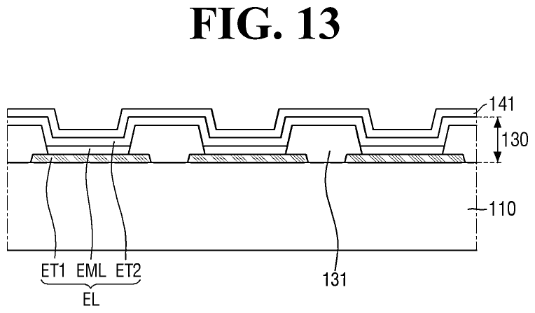

Referring to FIG. 13, the first inorganic encapsulation layer 141 may be formed on the light emitting elements EL (step S20). The first inorganic encapsulation layer 141 may be formed of a single inorganic insulating layer, but the disclosure is not limited thereto. The first inorganic encapsulation layer 141 may include multiple inorganic insulating layers.

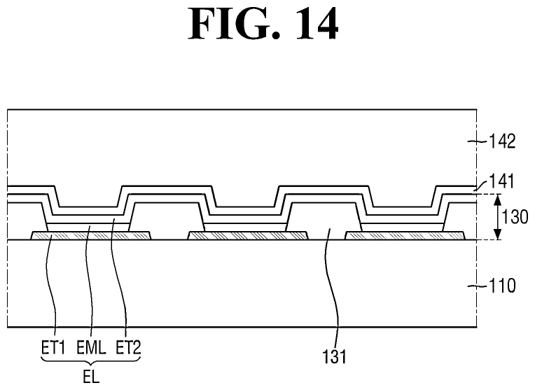

Referring to FIG. 14, the organic encapsulation layer 142 may be formed on the first inorganic encapsulation layer 141 (step S30). The organic encapsulation layer 142 may include an organic insulating material. The formation process of the organic encapsulation layer 142 is not particularly limited. For example, the organic encapsulation layer 142 may be formed by a chemical vapor deposition (CVD) process or an inkjet printing process.

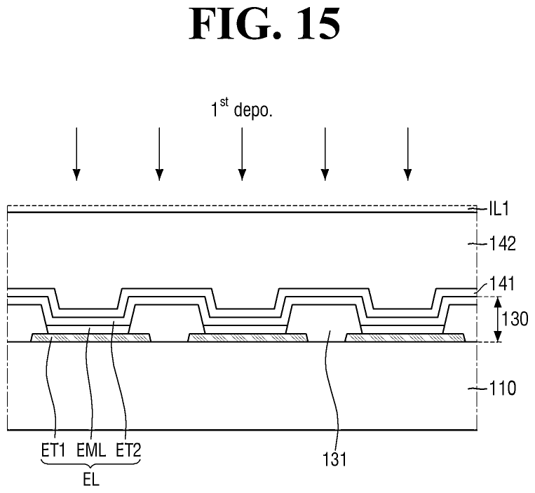

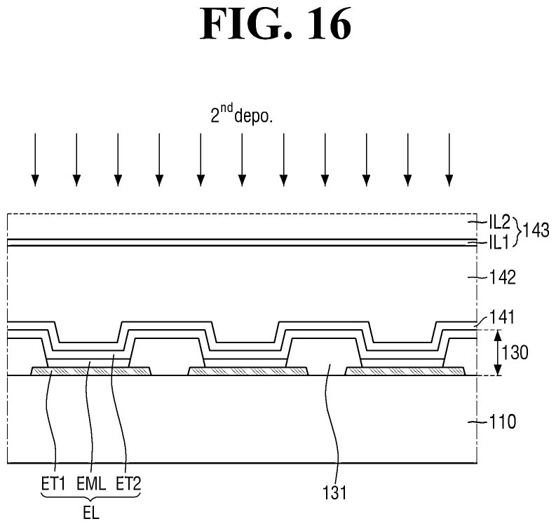

Referring to FIGS. 15 and 16, the second inorganic encapsulation layer 143 may be formed on the organic encapsulation layer 142 (step S40). The step of forming the second inorganic encapsulation layer 143 may include forming the first inorganic layer IL1 shown in FIG. 15 (step S41), and forming the second inorganic layer IL2 on the first inorganic layer IL1 shown in FIG. 16 (step S42).

Referring to FIG. 15, the first inorganic layer IL1 may be formed on the organic encapsulation layer 142 at a first deposition rate (step S41). Step S41 of forming the first inorganic layer IL1 may be performed using a plasma atomic layer deposition (PEALD) or plasma chemical vapor deposition (PECVD) process.

Referring to FIG. 16, the second inorganic layer IL2 may be formed on the first inorganic layer IL1 at a second deposition rate (step S42). Step S42 of forming the second inorganic layer IL2 may be performed using a plasma atomic layer deposition (PEALD) or plasma chemical vapor deposition (PECVD) process.

Step S41 of forming the first inorganic layer IL1 and step S42 of forming the second inorganic layer IL2 may be performed using a same aminosilane precursor. The aminosilane precursor may have an Si—N bond as a core structure, and may include at least one of cyclosilazane, trisilylamine, bis(diethylamino)silane (BDEAS), bis(t-butylamino)silane (BTBAS), tris(dimethylamino)silane, tris(isopropylamino)silane, tetrakis(dimethylamino)silane, tri(isopropyl)cyclotrisilazane, and tetramethyldisilazane, but the disclosure is not limited thereto.

In an embodiment, the first deposition rate may be less than the second deposition rate. The first deposition rate may be less than or equal to about 300 Å/min, and the second deposition rate may be greater than and equal to about 300 Å/min. Accordingly, the film density of the first inorganic layer IL1 may be greater than the film density of the second inorganic layer IL2.

Step S42 of forming the second inorganic layer may include allowing the particles of the first inorganic layer IL1 to penetrate into the second inorganic layer IL2. At the interface between the first inorganic layer IL1 and the second inorganic layer IL2, the particles of the first inorganic layer IL1 may move to the second inorganic layer IL2, thereby increasing the density of the lower portion of the second inorganic layer IL2.

In FIGS. 10 to 16, it is illustrated that step S40 of forming the second inorganic encapsulation layer 143 includes step S41 of forming the first inorganic layer IL1 and step S42 of forming the second inorganic layer IL2 on the first inorganic layer IL1, but the disclosure is not limited thereto, and in another embodiment, the step S20 of forming the first inorganic encapsulation layer 141 may also include forming the first inorganic layer IL1_1 and forming the second inorganic layer IL2_1 on the first inorganic layer IL1_1.

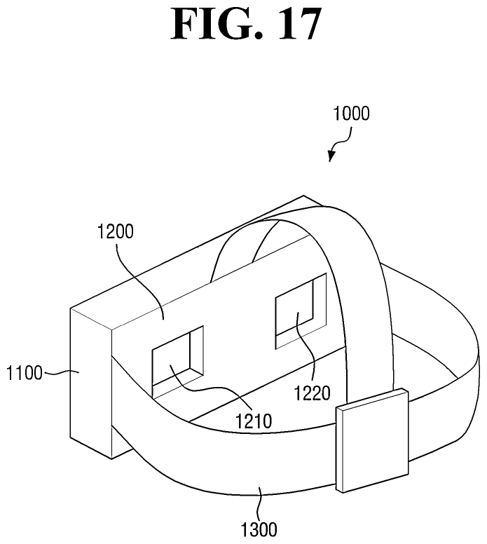

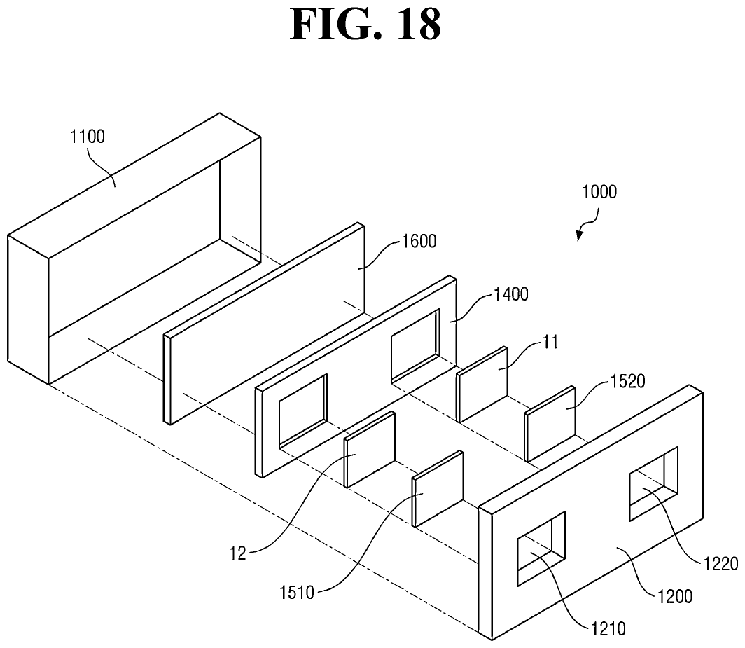

FIG. 17 is a perspective view illustrating a head mounted display according to one embodiment. FIG. 18 is an exploded perspective view showing an example of the head mounted display of FIG. 17.

Referring to FIGS. 17 and 18, a head mounted display 1000 according to one embodiment may include a first display device 11, a second display device 12, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector.

The first display device 11 may provide an image to a user's left eye, and the second display device 12 may provide an image to a user's right eye. Since each of the first display device 11 and the second display device 12 is substantially the same as the display device 10 described in conjunction with FIG. 1, the description of the first display device 11 and the second display device 12 will be omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1400 may be disposed between the first display device 11 and the control circuit board 1600 and between the second display device 12 and the control circuit board 1600. The middle frame 1400 may serve to support and fix the first display device 11, the second display device 12, and the control circuit board 1600.

The control circuit board 1600 may be disposed between the middle frame 1400 and the display device housing 1100. The control circuit board 1600 may be connected to the first display device 11 and the second display device 12 through the connector. The control circuit board 1600 may convert an image source input from the outside into the digital video data DATA, and may transmit the digital video data DATA to the first display device 11 and the second display device 12 through the connector.

The control circuit board 1600 may transmit the digital video data DATA corresponding to a left-eye image optimized for the user's left eye to the first display device 11, and may transmit the digital video data DATA corresponding to a right-eye image optimized for the user's right eye to the second display device 12. In another embodiment, the control circuit board 1600 may transmit a same digital video data DATA to the first display device 11 and the second display device 12.

The display device housing 1100 may serve to accommodate the first display device 11, the second display device 12, the middle frame 1400, the first optical member 1510, the second optical member 1520, the control circuit board 1600, and the connector. The housing cover 1200 may cover an open surface of the display device housing 1100. The housing cover 1200 may include the first eyepiece 1210 at which the user's left eye is disposed and the second eyepiece 1220 at which the user's right eye is disposed. FIGS. 17 and 18 schematically illustrate that the first eyepiece 1210 and the second eyepiece 1220 are disposed separately, but the disclosure is not limited thereto. The first eyepiece 1210 and the second eyepiece 1220 may be integral with each other.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head mounted band 1300 may serve to secure the display device housing 1100 to the user's head such that the first eyepiece 1210 and the second eyepiece 1220 of the housing cover 1200 remain disposed on the user's left and right eyes, respectively. In case that the display device housing 1200 is implemented to be lightweight and compact, the head mounted display 1000 may be provided with, as shown in FIG. 17, an eyeglass frame instead of the head mounted band 1300.

In an embodiment, the head mounted display 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

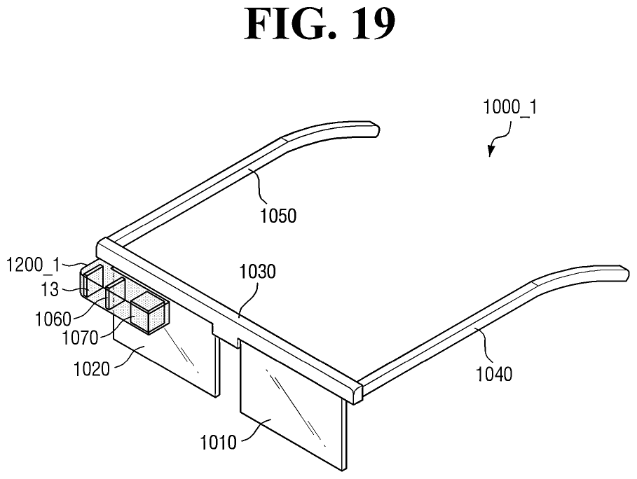

FIG. 19 is a perspective view illustrating a head mounted display according to one embodiment.

Referring to FIG. 19, a head mounted display 1000_1 according to one embodiment may be an eyeglasses-type display device in which a display device housing 1200_1 is implemented in a lightweight and compact manner. The head mounted display 1000_1 according to one embodiment may include a display device 13, a left eye lens 1010, a right eye lens 1020, a support frame 1030, temples 1040 and 1050, an optical member 1060, an optical path changing member 1070, and the display device housing 1200_1.

The display device housing 1200_1 may include the display device 13, the optical member 1060, and the optical path changing member 1070. An image displayed on the display device 13 may be magnified by the optical member 1060, and the optical path may be changed by the optical path changing member 1070 to provide the image to the user's right eye through the right eye lens 1020. As a result, the user may view an augmented reality image, through the right eye, in which a virtual image displayed on the display device 13 and a real image seen through the right eye lens 1020 may be combined.

FIG. 19 schematically illustrates that the display device housing 1200_1 is disposed at the right end of the support frame 1030, but the disclosure is not limited thereto. For example, the display device housing 1200_1 may be disposed on the left end of the support frame 1030, and the image of the display device 13 may be provided to the user's left eye. In another embodiment, the display device housing 1200_1 may be disposed on both the left and right ends of the support frame 1030, and the user may view the image displayed on the display device 13 through both the left and right eyes.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting element layer disposed on a substrate and comprising a plurality of light emitting elements; and
an encapsulation layer comprising a first inorganic encapsulation layer disposed on the light emitting element layer, an organic encapsulation layer disposed on the first inorganic encapsulation layer, and a second inorganic encapsulation layer disposed on the organic encapsulation layer, wherein
at least one of the first inorganic encapsulation layer and the second inorganic encapsulation layer comprises a first inorganic layer and a second inorganic layer disposed on the first inorganic layer,
the second inorganic layer comprises a first surface facing the first inorganic layer, and a second surface opposite to the first surface,
a first film density of the second inorganic layer in a region adjacent to the first surface of the second inorganic layer is greater than a second film density of the second inorganic layer in a region adjacent to the second surface of the second inorganic layer, and
a film density of the first inorganic layer is greater than the second film density of the second inorganic layer.

2. The display device of claim 1, wherein a thickness of the first inorganic layer is in a range of about 3 Å to about 20 Å.

3. The display device of claim 1, wherein the second inorganic layer further has a third film density, which is smaller than the first film density and greater than the second film density, between the first surface and the second surface.

4. The display device of claim 3, wherein the second inorganic layer further comprises a region where a film density of the second inorganic layer decreases.

5. The display device of claim 4, wherein the film density of the second inorganic layer decreases in a thickness direction.

6. The display device of claim 4, wherein a thickness of the region where the film density of the second inorganic layer decreases is about 10 to about 50 times a thickness of the first inorganic layer.

7. The display device of claim 4, wherein a thickness of the region where the film density of the second inorganic layer decreases is about 5% to about 40% of a total thickness of the second inorganic layer.

8. The display device of claim 1, wherein a difference between the film density of the first inorganic layer and the second film density of the second inorganic layer is greater than or equal to about 0.5.

9. The display device of claim 1, wherein each of the first inorganic layer and the second inorganic layer comprises silicon nitride.

10. The display device of claim 1, wherein a refractive index of the first inorganic layer is greater than or equal to about 1.9.

11. The display device of claim 10, wherein a refractive index of the second inorganic layer is in a range of about 1.7 to about 1.8.

12. The display device of claim 1, wherein
the first inorganic encapsulation layer comprises the first inorganic layer and the second inorganic layer, and
a thickness of the first inorganic encapsulation layer is less than or equal to about 600 Å.

13. The display device of claim 1, wherein
the second inorganic encapsulation layer comprises the first inorganic layer and the second inorganic layer, and
a thickness of the second inorganic encapsulation layer is less than or equal to about 1200 Å.

14. A display device comprising:
a light emitting element layer disposed on a substrate and comprising a plurality of light emitting elements;
a first inorganic encapsulation layer comprising a first inorganic layer disposed on the light emitting element layer and a second inorganic layer disposed on the first inorganic layer;
an organic encapsulation layer disposed on the first inorganic encapsulation layer; and
an encapsulation layer comprising a second inorganic encapsulation layer comprising a third inorganic layer disposed on the organic encapsulation layer, and a fourth inorganic layer disposed on the third inorganic layer, wherein
the second inorganic layer comprises a region where a film density of the second inorganic layer decreases in a thickness direction, and
the fourth inorganic layer comprises a region where a film density of the fourth inorganic layer decreases in the thickness direction.

15. The display device of claim 14, wherein
a film density of the first inorganic layer is greater than a maximum film density of the second inorganic layer, and
a film density of the third inorganic layer is greater than a maximum film density of the fourth inorganic layer.

16. The display device of claim 14, wherein each of a water vapor transmission rate of the first inorganic encapsulation layer and a water vapor transmission rate of the second inorganic encapsulation layer is less than or equal to about 9*10⁻⁴ g/m² day.

17. A method of fabrication for a display device, comprising:
forming a light emitting element layer comprising a plurality of light emitting elements on a substrate;
forming a first inorganic encapsulation layer on the light emitting element layer;
forming an organic encapsulation layer on the first inorganic encapsulation layer; and
forming a second inorganic encapsulation layer on the organic encapsulation layer, wherein
the forming of the first inorganic encapsulation layer or the forming of the second inorganic encapsulation layer comprises:
forming a first inorganic layer at a first deposition rate; and
forming a second inorganic layer on the first inorganic encapsulation layer at a second deposition rate, and
the first deposition rate is less than the second deposition rate.

18. The method of claim 17, wherein the forming of the second inorganic layer comprises allowing particles of the first inorganic layer to penetrate into the second inorganic layer.

19. The method of claim 17, wherein the forming of the first inorganic layer and the forming of the second inorganic layer are performed using an aminosilane precursor.

20. The method of claim 19, wherein the aminosilane precursor comprises at least one of cyclosilazane, trisilylamine, bis(diethylamino)silane (BDEAS), bis(t-butylamino)silane (BTBAS), tris(dimethylamino)silane, tris(isopropylamino)silane, tetrakis(dimethylamino)silane, tri(isopropyl)cyclotrisilazane, and tetramethyldisilazane.
